(19) United States
(12) Patent Application Publication
(10) Pub. No.: US 2021/0211151 A1
(43) Pub. Date: Jul. 8, 2021

(54) Removable magnetic phone protection case with EMR blocking

(71) Applicant: Squab Holland Holdings LLC, Vadnais Heights, MN (US)

(72) Inventor: Drew Bergstrom, Vadnais Heights, MN (US)

(21) Appl. No.: 16/829,589

(22) Filed: Mar. 25, 2020

Related U.S. Application Data
(60) Provisional application No. 62/958,073, filed on Jan. 7, 2020.

(51) Int. Cl. H04B 1/3827; H04B 1/3888; H05K 7/14

(52) U.S. Cl. CPC H04B 1/3838; H01F 3/00; H05K 7/1427; H04B 1/3888

(57) ABSTRACT

A removable case for protecting a mobile communication device having one or more areas of conductive thickness positioned at selected locations for providing protection to a user from electromagnetic radiation received by or emitted from the mobile communication device. The case is comprised of a resin, plastic carbon fiber, silicon, metals or combinations thereof. The one or more areas having a conductive thickness comprise a conductive plastic material for EMI shielding comprising a blend of polyetherimide (PEI), a blend of polybutylene terephthalate (PBT), blends of polycarbonate (PC)/Acrylonitrile Butadiene Styrene (ABS) plastic alloys, conductive fillers, or a combination thereof.

### CROSS-REFERENCE TO RELATED APPLICATION

This application is based on and claims the benefit of U.S. provisional application Ser. No. 62/958,073, filed Jan. 7, 2020, the content of which is hereby incorporated in its entirety.

### BACKGROUND

Power density and data exchange rates for cellular communication devices have grown at an exponential rate and according to Moore's Law. To support this exponential growth and demand for larger and faster data transfer, and constant communication demands from various applications, engineers have moved mobile device communication protocol up the frequency charts from radio waves to microwaves and mm waves. The difference in energy magnitude between radio waves and microwaves is significant.

As cell phones emit an electromagnetic frequency, a form of non-ionizing radiation, from their antennas, parts of the user's body nearest to the antenna absorb energy. Various health effects have been studied and reported, related to cell phone use and the corresponding electromagnetic radiation. These effects include the disruption of biological systems, apoptosis, and cellular and lymphatic function, neurologic effects in young people, when biological systems are proximate to the cell phone.

There were over 400 million cell phone subscribers in the United States in 2017, and globally, there are more than 5 billion cell phone users according to the Cellular Telecommunications and Internet Association.

### SUMMARY

An aspect of the present disclosure relates to a removable case for a mobile communication device. The removable case has a shell for covering at least a portion of the mobile communication device and for providing impact protection to the mobile communication device when received therein. One or more areas of the shell have a conductive thickness wherein the conductive thickness is positioned at selected locations for providing protection to a user from electromagnetic radiation emitted from the mobile communication device secured within the removable case.

The shell is comprised of a resin, plastic carbon fiber, silicon, metals or combinations thereof.

The one or more areas having a conductive thickness comprise a magnetically and electrically excitable material, a ferrous material, a ferromagnetic material, conductive plate, conductive mesh or combinations thereof.

The one or more areas having a conductive thickness comprise a conductive plastic material.

The one or more areas having a conductive thickness comprise a conductive plastic for EMI shielding comprising a blend of polyetherimide (PEI), a blend of polybutylene terephthalate (PBT), blends of polycarbonate (PC)/Acrylonitrile Butadiene Styrene (ABS) plastic alloys, conductive fillers, or a combination thereof.

The one or more areas having a conductive thickness have one or more dimensions and geometries.

The one or more areas having a conductive thickness comprise at least one area proximate to an antenna location of the mobile communication device.

The removable case is produced by over molding, two material two shot molding, impregnating a thermoplastic or combinations thereof.

A ferrous core is integrated therein at one or more locations within a thickness of the shell to allow for magnetic mounting of the removable case.

An auxiliary battery or battery supply can be incorporated into the case.

Another aspect of the present disclosure relates to a removable case for a mobile communication device having a shell for covering at least a portion of the mobile communication device and for providing impact protection to the mobile device installed therein. One or more locations of the shell are comprised of a conductive plastic for providing protection to a user from electromagnetic radiation received by or emitted from the mobile communication for which the removable case is designed.

The removable case further has a printed circuit board (PCB) integrated into the case, a ferrous core integrated into the case, an auxiliary battery or battery supply therein, or combinations thereof.

### BRIEF DESCRIPTION OF THE DRAWINGS

FIG. 1 is front view of a phone case according embodiments described herein.

FIG. 2 is side view of the phone case.

FIG. 3 is a bottom view of the phone case.

FIG. 4 is a cross-sectional view of the case about line A-A.

### DETAILED DESCRIPTION

A removable case for a mobile communication device, such as a cellular phone, wherein the case protects the mobile device from damage due to physical impact and shock. The case has at least one surface that is magnetic such that the case can be magnetically coupled to a magnetized surface to removably secure the mobile device to a magnetic surface. The case is also designed and constructed so the surfaces near the antenna on the mobile device contain conductive materials of a certain ratio to protect a user from electromagnetic radiation (EMR) including in a high frequency microwave band emitted from one or more areas of the mobile device.

A fundamentally different mobile or cellular phone case that shields the user from, for example, three danger surfaces of the mobile device and concurrently allows for magnetic fixation of the case, with or without a mobile device therein, on any magnetic surface. The case is also configured to shield the user's body from most background cellular communication, which happens when the user is not providing inputs to the mobile device or when the device may be in a standby mode.

The case does not incorporate the shielding construction or material on or around the entire mobile device, as to do so would prevent the mobile device from communicating with networks including cellular and wireless internet networks. Toeing the line between effective shielding and good communication is where the case of the present disclosure finds its niche. The case may be effective at shielding a user from EMR when the supported mobile device is in a pocket in clothing, in a user's hands, held to the user's ear, or on a bedside table.

The case according to embodiments herein is designed to attenuate electromagnetic waves at or emitted from one or more areas of the mobile device near an antenna of the mobile device. While the location of the antenna(s) can vary by mobile device manufacturer and model, generally the antenna is positioned on thin sides and a rear of the phone, or an upper area of the device.

The case comprises a conductive material which may be embedded in an outer case housing material. The outer case housing generally matches the geometry of the specific mobile device model in size and shape in order to snugly fit the mobile device and secure to the outer surface of the mobile device. In the standard way, the case provides opening for the interface and display of the mobile device as well as camera. For example, the overall construction of the case may be a hard plastic or a silicon material, or a like material which provides impact protection for the mobile device. The shielding material may be selectively embedded between layers of material forming the housing of the case, or co-molded therewith within a thickness of the material, or otherwise provided in a thickness of the case housing material at one or more selected locations.

The geometry of the area and position of the conductive material with respect to the outer case housing material is one that is effective for the wavelengths described. The conductive material may be referred to an interior piece(s) of the outer case housing. While these interior piece(s) function to attenuate EMR according to Lenz's Law, it is also contemplated and within the scope of this disclosure the possibility and ability to co-design an additional and potentially different functionality of the case by providing a magnetic function to the case, allowing the case to be magnetically fixed to magnetic surfaces for storage, for example. Thus the case can have an overall magnetic field that aligns the spins of unpaired electrons in one or more metal surfaces of or within the case in such a way to attract the case to other metal surfaces with sufficient force to stick the case with a phone therein to the metal surface.

The interior pieces contain a magnetically and electrically excitable metal, such as a ferrous metal, close to a rear surface of the case or a surface opposite of the user interface. This geometry and proximity allow for the phone to be mounted on any magnetic surface by friction and magnetic lock due to aligning electron fields.

In one embodiment, the interior pieces may be comprised of a conductive material in plate form having various dimensions and geometries, a conductive mesh, or a ferromagnetic material for example.

In an additional or alternative embodiment, the case may be constructed from, or comprise one or more areas constructed from a conductive plastic for EMI shielding. Such materials are plastics impregnated with a conductive material in the form of fibers or pellets. Examples include, but are not limited to, a conductive plastic form EMI shielding comprising a blend of polyetherimide (PEI), a blend of polybutylene terephthalate (PBT), blends of polycarbonate (PC)/Acrylonitrile Butadiene Styrene (ABS) plastic alloys and conductive fillers, or combinations thereof, such that the areas of the case comprising a conductive material for EMI shielding comprise one or more materials that deliver excellent shielding effectiveness, and impact resistance to the finished case. Examples of conductive fillers include but are not limited to carbon, steel, carbon fibers and combinations thereof.

The case itself may comprise or be constructed of one or more materials, for example, including areas constructed from conductive plastic and other areas constructed from non-conductive plastic, silicon, metals, or combinations thereof.

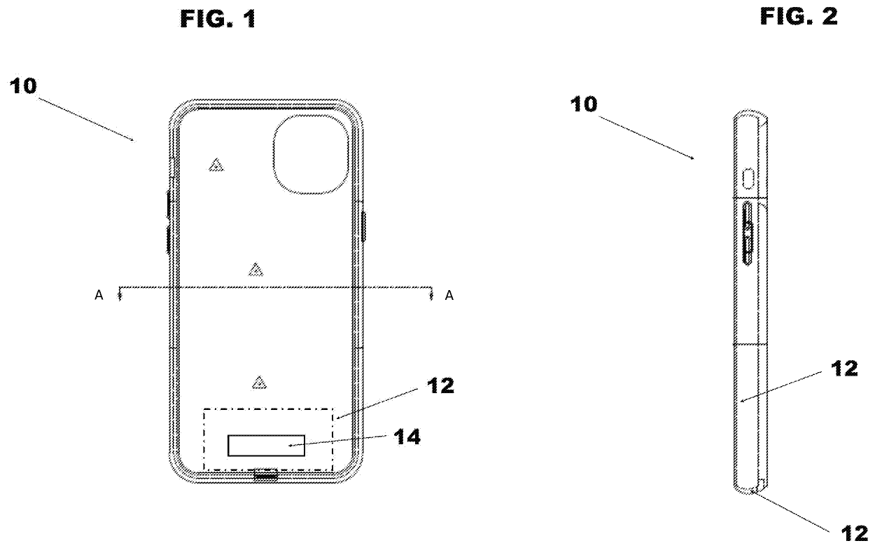

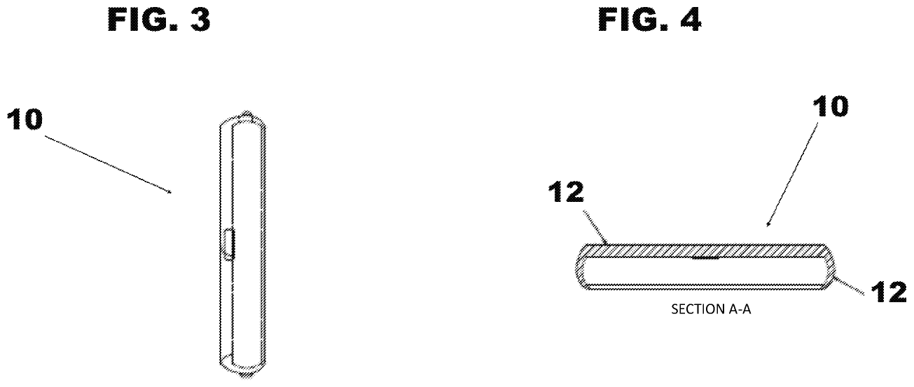

One embodiment of the case according to the description herein is illustrated at 10 in FIGS. 1-4. The case 10 has conductive areas 12 selectively positioned for EMR shielding. These areas may change due to the mobile device model the case 10 is configured to fit. However, in general, the conductive material areas 12 are positioned, for example, along sides of the case 10 and/or along a back surface of the case 10. The conductive areas, also referred to as shielding areas 12 are positioned at one or more critical areas. The critical areas may be areas where EMR is strongest, such as around or near a location of a charging port or an antenna 14 of the device the case 10 is configured for use in connection with. In one embodiment, where plates of conductive materials are provided within the case 10, the case 10 may then have an opening in the depth range or diameter range of about 0.04 to about 0.06 inches for receipt of interior conductive sheets or pieces of the shielding material as described herein. In embodiments where the shielding areas are constructed of conductive plastics, the conductivity level of the plastic material used is controlled and thickness of the case 10 is consistent throughout its surface area.

The case 10 may further comprise a printed circuit board (PCB) integrated into the case or otherwise secured thereto or therein.

The case 10 may further comprise a ferrous core integrated therein or otherwise provided at one or more locations within or on the case. The ferrous core allows for magnetic mounting of the case 10 and any phone or accessory supported therein.

The case 10 may further comprise an auxiliary battery or battery supply therein or thereon to provide an additional power source to the phone or accessory supported therein. The auxiliary battery is connectable to the phone or accessory for purposes of charging the phone or accessory when additional power sources such as an outlet or charging pad are not available.

Methods used to manufacture the case described herein including the interior pieces positioned within the thickness of the outer case housing include but are not limited to over molding, 2K injection molding (e.g., two material two shot molding), impregnated thermoplastics and/or combinations thereof.

The case according to embodiments herein comprises an impregnated engineered material, such as a plastic material, wherein the case is selectively impregnated and thus configured to attenuate EM waves at or near selected areas of the case. For example, locations on the case near a location of an antenna of the mobile device for which the case is suited are to be impregnated with the materials described herein for attenuating the EM waves. The closer a user is to such areas on a mobile device, the more EM waves or energy the user will absorb. In one embodiment, where for example, the case has dimensions designed for use with an Apple™ iPhone™, areas on the phone and thus the corresponding case near and/or surrounding the antenna or charging port require attenuation. Thus, the position and/or location of the conductive material in the case or the areas in which conductive material for shielding is present will vary in the case due to the model of mobile device the case dimensions are configured for use. As the locations of proximate shielding regions change for case construction according to mobile device models and the locations of the antennas of each mobile device, generally in the proximate regions electrodynamic studies show shielding effectiveness where the design of attenuation materials (e.g., conductive materials, conductive plastics) exceeds the antenna volume by 5.5 times in three dimensions.

In cross-section, the shielding materials within the case, may have a thickness sufficient to have effective attenuation properties for the wavelength described as x>70 db. The conductivity of the impregnated plastic is directly proportional to the amount of attenuation the material has (e.g., 70 db). The cases according to embodiments described herein are configured to achieving 70 db of attenuation for EMR shielding purposes. In this embodiment, as illustrated in the FIGS., the walls of the case near and/or abutting the opening for access to the charging part are impregnated with the EM attenuating materials.

Although the present disclosure has been described with reference to preferred embodiments, workers skilled in the art will recognize that changes may be made in form and detail without departing from the spirit and scope of the disclosure.

1. A removable case for a mobile communication device comprising:
a shell for covering at least a portion of the mobile communication device and for providing impact protection to the mobile communication device installed therein;
one or more areas of the shell having a conductive thickness therein wherein the conductive
thickness is positioned at selected locations for providing protection to a user from electromagnetic radiation received by or emitted from the mobile communication device secured within the removable case;
wherein the shell is comprised of a resin, plastic carbon fiber, silicon, metals or combinations and the conductive thickness is embedded integrally within the shell at the one or more areas.

2. The removable case of claim 1 wherein the shell is comprised of a resin, plastic carbon fiber, silicon, metals or combinations thereof.

3. The removable case of claim 1 wherein the one or more areas having a conductive thickness comprise a magnetically and electrically excitable material, a ferrous material, a ferromagnetic material, conductive plate, conductive mesh or combinations thereof.

4. The removable case of claim 1 wherein the one or more areas having a conductive thickness comprise a conductive plastic material.

5. The removable case of claim 1 wherein the one or more areas having a conductive thickness comprise a conductive plastic for EMI shielding comprising a blend of polyetherimide (PEI), a blend of polybutylene terephthalate (PBT), blends of polycarbonate (PC)/Acrylonitrile Butadiene Styrene (ABS) plastic alloys, conductive fillers, or a combination thereof.

6. The removable case of claim 1 wherein the one or more areas having a conductive thickness have one or more dimensions and geometries.

7. The removable case of claim 1 wherein the one or more areas having a conductive thickness comprise at least one area proximate an antenna location of the mobile communication device.

8. The removable case of claim 1 wherein the case is produced by over molding, two material two shot molding, impregnating a thermoplastic or combinations thereof.

9. The removable case of claim 5 wherein the conductive fillers comprise carbon, steel, carbon fibers, and combinations thereof.

10. The removable case of claim 1 and further comprising a ferrous core integrated therein at one or more locations within a thickness of the shell to allow for magnetic mounting of the removable case.

11. The removable case of claim 1 and further comprising an auxiliary battery or battery supply therein.

12. A removable case for a mobile communication device comprising:
a shell for covering at least a portion of the mobile communication device and for providing impact protection to the mobile device installed therein; and
one or more locations of the shell comprised of a conductive plastic for providing protection to a user from electromagnetic radiation received by or emitted from the mobile communication for which the removable case is designed; and
wherein the shell is formed from a resin, plastic carbon fiber, silicon, metal or combinations thereof.

13. The removable case of claim 10 and further comprising a printed circuit board (PCB) integrated into the case, a ferrous core integrated into the case, an auxiliary battery or battery supply therein, or combinations thereof.

14. The removable case of claim 1 and further comprising one or more depressions on a rear face of the removable case.
